(19) United States
(12) Patent Application Publication
(10) Pub. No.: US 2022/0390992 A1
(43) Pub. Date: Dec. 8, 2022

(54) FIELD-REPLACEABLE UNIT IDENTIFICATION CIRCUIT

(71) Applicant: Quanta Computer Inc., Taoyuan City (TW)

(72) Inventors: Chia-Ming LIANG, Taoyuan City (TW); Jen-Mao CHEN, Taoyuan City (TW); Hsiao-Ching CHEN, Taoyuan City (TW); Yu-Tang ZENG, Taoyuan City (TW)

(21) Appl. No.: 17/342,237

(22) Filed: Jun. 8, 2021

(51) Int. Cl. G06F 1/20; H05K 7/14; H03K 5/24; H05K 7/20

(52) U.S. Cl. CPC G06F 1/20; H05K 7/1427; H03K 5/24; H05K 7/20172; H05K 7/20718

(57) ABSTRACT

A field-replaceable unit (FRU) identification circuit includes a reference voltage source, a reference resistor, a plurality of comparators, and a plurality of comparator input voltage sources. The reference voltage source provides a reference voltage. A first end of the reference resistor is electrically connected to the reference voltage source. Each comparator has two inputs and an output. A first input of each comparator is electrically connected to a second end of the reference resistor. The comparator input voltage sources each provide a comparator input voltage to the second input of one of the comparators. When an FRU is electrically connected to a circuit board where the FRU identification circuit is located, the outputs of the comparators are set to a distinct combination of logical values that uniquely identifies the FRU.

### TECHNICAL FIELD

The present disclosure relates generally to systems and devices for identifying field-replaceable units in computing systems. More particularly, aspects of this disclosure relate to a circuit that allows a field-replaceable fan module to be identified.

### BACKGROUND

Many computing systems (such as servers) utilize field-replaceable units that can be easily added to or removed from a circuit board of a computing device. For example, servers often utilize field-replaceable fan modules that can be connected to the circuit board of the server. These fan modules can easily be removed for a variety of purposes, such as maintenance or replacement. These fan modules often contain an electronic memory device (such as an EEPROM) storing certain information related to the fan module. This stored information can include identification information, security information, etc., which can be helpful in identifying and servicing the fan module. For example, the stored information can be used to identify the manufacturer or vendor of the fan module. However, relying on electronic memory devices to identify the fan modules can increase the complexity and the cost of both the fan modules and the circuit board. Thus, new systems and devices for identifying field-replaceable fan modules (or other field-replaceable units) are desirable.

### SUMMARY

The term embodiment and like terms are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter; nor is it intended to be used in isolation to determine the scope of the claimed subject matter. The subject matter should be understood by reference to appropriate portions of the entire specification of this disclosure, any or all drawings and each claim.

In a first implementation, the present disclosure is directed toward a field-replaceable unit (FRU) identification circuit configured to identify an FRU electrically connected to a circuit board. The FRU identification circuit includes a reference voltage source, a reference resistor, a plurality of comparators, and a plurality of comparator input voltage sources. The reference voltage source is configured to provide a reference voltage. The reference resistor has a first end and a second end. The first end of the reference resistor is electrically connected to the reference voltage source. Each of the plurality of comparators has a first input, a second input, and an output. The first input of each of the plurality of comparators is electrically connected to the second end of the reference resistor. Each of the plurality of comparator input voltage sources is configured to provide a comparator input voltage, and is electrically connected to the second input of a respective one of the plurality of comparators. In response to the FRU being electrically connected to the circuit board, the outputs of the plurality of comparators are set to a distinct combination of logical values that uniquely identifies the FRU.

In some cases, the FRU includes a source resistor, and the reference voltage source, the reference resistor, and the source resistor form a voltage divider when the FRU is electrically connected to the circuit board. The voltage divider included a voltage divider output formed between the reference resistor and the source resistor. In some cases, when the FRU is electrically connected to the circuit board, the voltage divider output is electrically connected to the first input of each of the plurality of comparators. In some cases, the output of each respective one of the plurality of comparators is a logical value based on a comparison between (i) a voltage of the voltage divider output and (ii) the comparator input voltage of the comparator input voltage source electrically connected to the respective one of the plurality of comparators. In some cases, the output of each respective one of the plurality of comparators is a logical high value or a logical low value.

In some cases, in response to the comparator input voltage of the respective one of the plurality of comparators being greater than the voltage of the voltage divider output, the output of the respective one of the plurality of comparators is set to a logical high value. In some cases, in response to the comparator input voltage of the respective one of the plurality of comparators being less than the voltage of the voltage divider output, the output of the respective one of the plurality of comparators is set to a logical low value.

In some cases, the voltage of the voltage divider output is less than the reference voltage provided by the reference voltage source. In some cases, the voltage of the voltage divider output is less than the comparator input voltage of at least one of the plurality of comparator input voltage sources.

In some cases, the FRU is a fan module. In some cases, the reference voltage is greater than about 0 volts and less than or equal to about 20 volts. In some cases, the reference voltage is about 12 volts. In some cases, the reference resistor has a resistance of about 1,000 ohms. In some cases, the source resistor has a resistance that is different than a resistance of the reference resistor. In some cases, each one of the plurality of comparator input voltages is different than a remainder of the plurality of comparator input voltages.

In some cases, the plurality of comparators includes n comparators, and the FRU identification circuit is configured to distinguish among n distinct FRU groups. In these cases, each distinct FRU group includes one or more FRUs having a distinct value of a characteristic, and is identifiable by the outputs of the n comparators. In some cases, the outputs of the n comparators are configured to generate at least n+1 distinct combinations of logical values. In some cases, one of the n+1 distinct combinations of logical values corresponds to no FRU being electrically connected to the circuit board. Each remaining combination of logical values of the n+1 combinations of logical values corresponds to a distinct one of the n FRU groups. In some cases, the one of the n+1 distinct combinations of logical values corresponding to no FRU being electrically connected to the circuit board includes the output of each of the plurality of comparators being set to a logical high value. In some cases, each remaining combination of logical values of the n+1 combinations of logical values includes the output of at least one of the plurality of comparators being set to a logical low value.

In a second implementation, the present disclosure is directed toward a computing device that includes a housing, a circuit board disposed inside the housing, and a field-replaceable unit (FRU) identification circuit formed on the circuit board. The FRU identification circuit includes a reference voltage source, a reference resistor, a plurality of comparators, and a plurality of comparator input voltage sources. The reference voltage source is configured to provide a reference voltage. The reference resistor has a first end and a second end. The first end of the reference resistor is electrically connected to the reference voltage source. Each of the plurality of comparators has a first input, a second input, and an output. The first input of each of the plurality of comparators is electrically connected to the second end of the reference resistor. Each of the plurality of comparator input voltage sources is configured to provide a comparator input voltage, and is electrically connected to the second input of a respective one of the plurality of comparators. In response to the FRU being electrically connected to the circuit board, the outputs of the plurality of comparators are set to a distinct combination of logical values that uniquely identifies the FRU.

In a third implementation, the present disclosure is directed toward a method of identifying a field-replaceable unit (FRU). The method includes installing the FRU in a computing device such that the FRU is electrically connected to a circuit board of the computing device. The method further includes determining a logical value of an output of each of a plurality of comparators on the circuit board of the computing device. The method further includes identifying, based on the logical value of the output of each of the plurality of comparators, a group to which the FRU belongs.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims.

### BRIEF DESCRIPTION OF THE DRAWINGS

The disclosure will be better understood from the following description of exemplary embodiments together with reference to the accompanying drawings.

FIG. 1 is a field-replaceable unit identification circuit, according to aspects of the present disclosure.

FIG. 2 is a table showing different combinations of outputs of the field-replaceable unit identification circuit of FIG. 1, according to aspects of the present disclosure.

The present disclosure is susceptible to various modifications and alternative forms. Some representative embodiments have been shown by way of example in the drawings and will be described in detail herein. It should be understood, however, that the invention is not intended to be limited to the particular forms disclosed. Rather, the disclosure is to cover all modifications, equivalents, and alternatives falling within the spirit and scope of the invention as defined by the appended claims.

### DETAILED DESCRIPTION

The present inventions can be embodied in many different forms. Representative embodiments are shown in the drawings, and will herein be described in detail. The present disclosure is an example or illustration of the principles of the present disclosure, and is not intended to limit the broad aspects of the disclosure to the embodiments illustrated. To that extent, elements, and limitations that are disclosed, for example, in the Abstract, Summary, and Detailed Description sections, but not explicitly set forth in the claims, should not be incorporated into the claims, singly or collectively, by implication, inference, or otherwise. For purposes of the present detailed description, unless specifically disclaimed, the singular includes the plural and vice versa; and the word “including” means “including without limitation.” Moreover, words of approximation, such as “about,” “almost,” “substantially,” “approximately,” and the like, can be used herein to mean “at,” “near,” or “nearly at,” or “within 3-5% of,” or “within acceptable manufacturing tolerances,” or any logical combination thereof, for example.

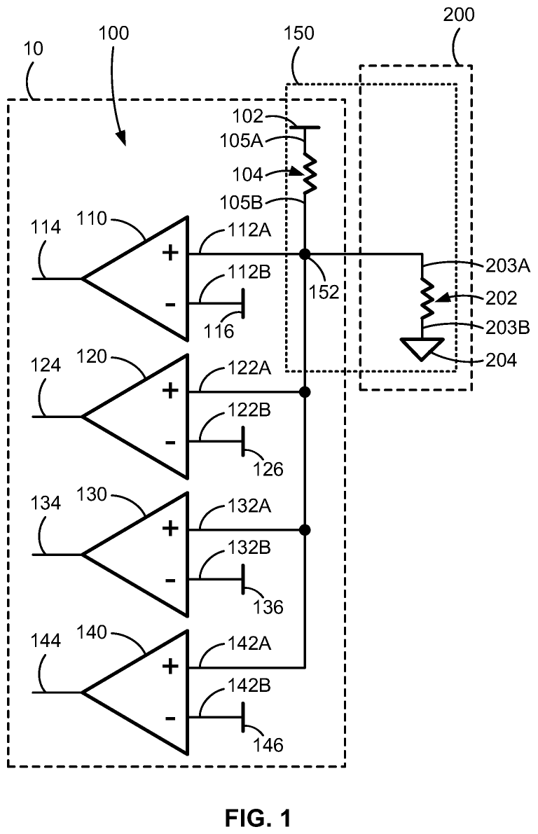

FIG. 1 illustrates a field-replaceable unit identification circuit 100 formed on a circuit board 10 of a computing device. The computing device (not shown) can include a housing (not shown), and the circuit board 10 and the field-replaceable unit identification circuit 100 can be disposed within the housing. In some implementations, the circuit board 10 can be a motherboard (also referred to as a main board, a system board, etc.) of the computing device. In some implementations, the computing device is a server. In some implementations, the FRU identification circuit 100 is integrally formed as part of the circuit board 10, e.g., when the circuit board 10 is printed, the circuit board 10 includes the FRU identification circuit 100. In other implementations, the FRU identification circuit 100 is a separate circuit module that can be electrically connected to the circuit board 10.

The circuit board 10 generally includes a number of other electronic components in addition to the field-replaceable unit identification circuit 100, and other electronic components may also be disposed in the housing of the computing device. FIG. 1 shows the circuit board 10 electrically connected to a field-replaceable unit (FRU) that has been received by the computing device. In the illustrated implementation, the FRU is a component of a fan module 200 (or is the fan module 200 itself) that can be used to cool the electronic components of the computing device during operation of the computing device. However, the FRU identification circuit 100 can be used to identify other types of FRUs as well. For example, the FRU can be a component of generally any device, including devices that include one or more printed circuit board assemblies, such as an add-on card, a memory module, etc. The FRU can also be the device itself in some implementations.

The FRU identification circuit 100 is configured to generate a combination of logical values that uniquely identifies the fan module 200 (or other FRU), or an FRU group to which the fan module 200 (or other FRU) belongs. FRUs such as the fan module 200 can be grouped according to any number of different characteristics or properties. In some implementations, different FRU groups correspond to different manufacturers and/or vendors of the fan module 200 (or other FRU). In implementations where the FRU is a fan module, the different FRU groups can be based on properties of fan modules, such as age, maximum fan speed, etc. Thus, each distinct FRU group corresponds to one or more FRUs that have a distinct value of a given characteristic. For example, when the characteristic is the manufacturer of the FRU, a first FRU group corresponds to FRUs manufactured by manufacturer A (a first value of the characteristic), a second FRU group corresponds to FRUs manufactured by manufacturer B (a second value of the characteristic), etc.

As shown in FIG. 1, the FRU identification circuit 100 includes a reference voltage source 102, a reference resistor 104, and comparators 110, 120, 130, and 140. Although the illustrated implementation shows four comparators, any number of comparators may be used. The number of comparators required depends on the number of different FRU groups to be identified. The reference voltage source 102 is configured to provide a reference voltage, and is electrically connected to a first end 105A of the reference resistor 104. In some implementations, the reference voltage provided by the reference voltage source 102 is greater than about 0 volts and less than or equal to about 20 volts. In some implementations, the reference voltage provided by the reference voltage source 102 is about 12 volts.

The first comparator 110 includes a first input 112A, a second input 112B, and an output 114. The second comparator 120 includes a first input 122A, a second input 122B, and an output 124. The third comparator 130 includes a first input 132A, a second input 132B, and an output 134. The fourth comparator 140 includes a first input 142A, a second input 142B, and an output 144.

The FRU identification circuit 100 includes a corresponding number of comparator input voltage sources that are each electrically connected to the second input 112B, 122B, 132B, and 142B of a respective one of the comparators 110, 120, 130, and 140. In the illustrated implementation, the plurality of comparator input voltage sources includes a first comparator input voltage source 116, a second comparator input voltage source 126, a third comparator input voltage source 136, and a fourth comparator input voltage source 146. Generally, the voltage of the reference voltage source 102 is greater than the voltages provided by each of the comparator input voltage sources 116, 126, 136, and 146.

The first comparator input voltage source 116 is electrically connected to the second input 112B of the first comparator 110. The second comparator input voltage source 126 is electrically connected to the second input 122B of the second comparator 120. The third comparator input voltage source 136 is electrically connected to the second input 132B of the third comparator 130. The fourth comparator input voltage source 146 is electrically connected to the second input 142B of the fourth comparator 140. Generally, each of the comparator input voltage sources 116, 126, 136, and 146 provide a constant voltage that is different than the constant voltage provided by the other comparator input voltage sources 116, 126, 136, and 146. Thus, the second input 112B, 122B, 132B, and 142B of each respective comparator 110, 120, 130, and 140 receives a different voltage.

The fan module 200 includes a source resistor 202 electrically connected to a ground 204. When the fan module 200 is installed in the computing device and electrically connected to the circuit board 10, a first end 203A of the source resistor 202 is electrically connected to a second end 105B of the reference resistor 104. Because a second end 203B of the source resistor 202 is connected to the ground 204, a voltage divider 150 is formed by the reference voltage source 102, the reference resistor 104, and the source resistor 202. The voltage divider 150 includes a voltage divider output 152 formed between the reference resistor 104 and the source resistor 202. The voltage divider output 152 is electrically connected to the first input 112A of the first comparator 110, the first input 122A of the second comparator 120, the first input 132A of the third comparator 130, and the fourth input 142A of the fourth comparator 140.

The voltage provided by the voltage divider output 152 is generally equal to the voltage provided by the reference voltage source 102, multiplied by the ratio of: (i) the resistance of the source resistor 202 to (ii) the resistance of the reference resistor 104 plus the resistance of the source resistor 202. Thus, if V_{ref} is the voltage of the reference voltage source 102, Vₒ is the voltage of the voltage divider output 152, R_{ref} is the resistance of the reference resistor 104, and Rₛ is the resistance of the source resistor 202, the voltage Vₒ of the voltage divider output 152 is determined by:

$${V}_{o} = {V}_{ref} \frac{{R}_{s}}{{R}_{ref} + {R}_{s}} .$$

In some implementations, the resistance of the reference resistor 104 is about 1,000Ω (ohms), or 1 kΩ. Generally, the resistance of the source resistor 202 is less than the resistance of the reference resistor 104. The voltage provided by the voltage divider output 152 is thus less than the reference voltage provided by the reference voltage source 102.

When the FRU identification circuit 100 is coupled to the circuit board 10, each of the comparators 110, 120, 130, and 140 is connected to both: (i) the voltage divider output 152; and (ii) one of the comparator input voltage sources 116, 126, 136, and 146. The comparators 110, 120, 130, and 140 are configured to output a logical value at their respective outputs 114, 124, 134, and 144 that is based on a comparison between: (i) a voltage of the voltage divider output 152; and (ii) the comparator input voltage of the comparator input voltage source 116, 126, 136, and 146 that is electrically connected to the respective one of the comparators 110, 120, 130, and 140.

In the illustrated implementation, the first inputs 112A, 122A, 132A, and 142A of the comparators 110, 120, 130, and 140 are positive inputs, while the second inputs 112B, 122B, 132B, and 142B of the comparators 110, 120, 130, and 140 are negative inputs. Thus, the outputs 114, 124, 134, and 144 will have a logical high value if the voltage of the voltage divider output 152 is greater than the voltage of the corresponding comparator input voltage sources 116, 126, 136, and 146 that is coupled to the second inputs 112B, 122B, 132B, and 142B. Correspondingly, the outputs 114, 124, 134, and 144 will have a logical low value if the voltage of the voltage divider output 152 is less than the voltage of the corresponding comparator input voltage sources 116, 126, 136, and 146 that is coupled to the second inputs 112B, 122B, 132B, and 142B. When the fan module 200 is coupled to the circuit board 10, the outputs 114, 124, 134, and 144 of the comparators 110, 120, 130, and 140 are set to either a logical high value or a logical low value, as is determined by the voltages that are present at the inputs of the comparators 110, 120, 130, and 140.

By ensuring that the voltages provided by the comparator input voltage sources 116, 126, 136, and 146 are all different from each other, coupling the fan module 200 to the circuit board 10 will set the outputs 114, 124, 134, and 144 of the comparators 110, 120, 130, 140 to a distinct combination of logical values. By using fan modules 200 with different resistance values of the source resistor 202, different fan modules 200 will result in different combinations of logical values at the outputs 114, 124, 134, and 144 of the comparators 110, 120, 130, and 140.

If all of the fan modules 200 within a given FRU group have the same resistance as the source resistor 202, and if the resistance of the source resistor 202 of each FRU group is distinct from the resistance of the source resistor 202 of all of the other FRU groups, then the combination of logical values of the outputs 114, 124, 134, and 144 of the comparators 110, 120, 130, and 140 can be used to identify the fan module 200, or the FRU group to which a given fan module 200 belongs.

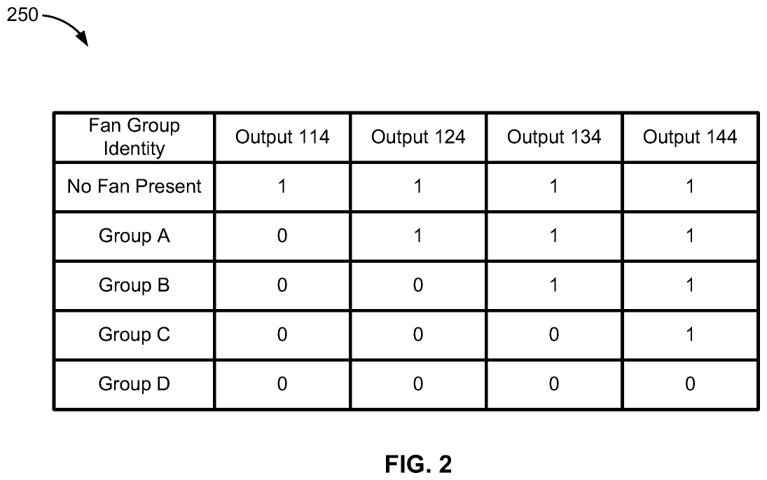

FIG. 2 illustrates a table 250 that shows the different combinations of the logical values of the outputs 114, 124, 134, and 144 that can result from four fan modules 200 that each belong to a distinct FRU group. The resistance of the source resistor 202 of each of the four fan modules 200 is different than the resistance of the source resistor 202 of all of the other fan modules 200. When no fan module is coupled to the circuit board 10, the voltage of the voltage divider output 152 is equal to the voltage of the reference voltage source 102. Because the voltage of the reference voltage source 102 is greater than the voltages of each of the comparator input voltage sources 116, 126, 136, and 146, the outputs 114, 124, 134, and 144 will each have a logical high value.

When a fan module 200 in Group A is coupled to the circuit board 10, the voltage of the voltage divider output 152 will be less than the voltage of the comparator input voltage source 116, and greater than the voltages of the comparator input voltage sources 126, 136, and 146. The fan modules 200 in Group A thus have a source resistor 202 with a resistance configured to generate a logical low value at output 114, and a logical high value at outputs 124, 134, and 144. When a fan module 200 in Group B is coupled to the circuit board 10, the voltage of the voltage divider output 152 will be less than the voltages of the comparator input voltage sources 116 and 126, and greater than the voltages of the comparator input voltage sources 136 and 146. The fan modules 200 in Group B thus have a source resistor 202 with a resistance configured to generate a logical low value at outputs 114 and 124, and a logical high value at outputs 134 and 144.

When a fan module 200 in Group C is coupled to the circuit board 10, the voltage of the voltage divider output 152 will be less than the voltages of the comparator input voltage sources 116, 126, and 136, and greater than the voltage of the comparator input voltage source 146. The fan modules 200 in Group C thus have a source resistor 202 with a resistance configured to generate a logical low value at outputs 114, 124, and 134, and a logical high value at output 144. When a fan module 200 in Group D is coupled to the circuit board 10, the voltage of the voltage divider output 152 will be less than the voltages of each of the comparator input voltage sources 116, 126, 136, and 146. The fan modules 200 in Group D thus have a source resistor 202 with a resistance configured to generate a logical high value at outputs 114, 124, 134, and 144.

Thus, as shown in FIG. 2, each of the four FRU groups results in a distinct combination of logical values at the outputs 114, 124, 134, and 144 of the comparators 110, 120, 130, and 140. When a fan module 200 is connected to the circuit board 10, the voltage of the voltage divider output 152 is generally less than the comparator input voltage of at least one of the comparator input voltage sources 116, 126, 136, and 146, meaning that at least one of the outputs 114, 124, 134, and 144 will have a logical low value. By examining the logical values of the outputs 114, 124, 134, and 144 when a given fan module 200 is connected to the circuit board 10, the FRU group to which the fan module 200 belongs to can be determined.

While FIG. 1 and FIG. 2 illustrate an embodiment that uses four comparators 110, 120, 130, and 140 to distinguish between fan modules belonging to four distinct FRU groups, the comparators in the FRU identification circuit 100 can include n comparators configured to distinguish between FRUs belong to n distinct FRU groups, where n is an integer greater than or equal to two. The outputs of the n comparators are configured to generate at least n+1 distinct combinations of logical values. One of these n+1 distinct combinations of logical values corresponds to the scenario where no FRU is electrically connected to the circuit board 10, while the remaining n distinct combinations of logical values each correspond to a scenario where an FRU from a distinct one of the n FRU groups is electrically connected to the circuit board 10. Similar to the results shown in FIG. 2, the one distinct combination of logical values that occurs when no FRU is electrically connected to the circuit board 10 can include the outputs of all of the n comparators being set to a logical high value. Similarly, each of the remaining n combinations of logical values that can occur when an FRU is electrically connected to the circuit board 10 can include the output of at least one of the n comparators being set to a logical low value.

Moreover, a variety of parameters of the FRU identification circuit 100 can be adjusted as needed. The voltage of the reference voltage source 102; the voltages of the comparator input voltage sources 116, 126, 136, and 146; the resistance of the reference resistor 104; and the resistance of the source resistor 202 in any FRU can be modified or adjusted if dictated by any design constraints or application constrains. In some implementations, the voltage of the reference voltage source 102 could be less than the voltages of the comparator input voltage sources 116, 126, 136, and 146. Further, while FIG. 2 shows the outputs of the comparators 110, 120, 130, and 140 having all logical high values when no FRU is electrically connected to the circuit board 10, in some implementations, the FRU identification circuit is designed so that the outputs of the comparators 110, 120, 130, and 140 will all have logical low values when no FRU is electrically connected to the circuit board 10. Similarly, in these implementations, the outputs of at least one of the comparators 110, 120, 130, and 140 will have a logical high value when an FRU is electrically connected to the circuit board 10.

The fan module 200 is shown in FIG. 1 as having a single source resistor 202 that forms part of the voltage divider 150 when the fan module 200 is electrically connected. However, in other implementations, other fan modules (or other types of FRUs) could have multiple resistors and/or other electrical components that form part of the voltage divider 150 when the fan module 200 is electrically connected. In these implementations, the FRU identification circuit 100 is designed to distinguish between the groups of resistors and/or other electrical components that may form part of the voltage divider 150 when the fan module 200 is electrically connected.

Further, while FIG. 1 shows that the FRU identification circuit 100 uses comparators 110-140 to compare the voltage divider output 152 to comparator input voltage sources 116, 126, 136, and 146, other components could also be used. For example, the comparators 110-140 could each be replaced by an integrated circuit that is able to compare the voltage divider output 152 to one of the comparator input voltage sources 116, 126, 136, and 146. In another example, the comparators 110-140 can be replaced by a single integrated circuit that is able to compare the voltage divider output 152 to each of the comparator input voltage sources 116, 126, 136, and 146. Generally, a variety of different components can be used to form the FRU identification circuit 100, so long as there is a distinct combination of logical values of the outputs of the comparators that uniquely identifies each FRU group.

Thus, in order to identify an FRU or an FRU group to which an FRU belongs, the FRU (such as the fan module 200) is installed in a computing device (such as a server), such that the FRU is electrically connected to a circuit board (such as circuit board 10) of the computing device. The output of an FRU identification circuit (such as FRU identification circuit 100) that is formed on the circuit board is then determined. As discussed herein, the output of the FRU identification circuit can be the distinct combination of logical values of the outputs of a plurality of comparators. Finally, the FRU and/or the FRU group is identified based on the output of the FRU identification circuit (e.g., the distinct combination of logical values of the outputs of the plurality of comparators). In some implementations, the computing device can include any hardware and/or software required to read the logical value of the output of the FRU identification circuit, and/or identify the FRU or the FRU group based on the output of the FRU identification circuit. In other implementations, a technician or user can aid in installing the FRU in the computing device, and can also manually determine the output of the FRU identification circuit and/or identify the FRU or the FRU group belongs, based on the output of the FRU identification circuit.

While various embodiments of the present invention have been described above, it should be understood that they have been presented by way of example only, and not limitation. Numerous changes to the disclosed embodiments can be made in accordance with the disclosure herein, without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations, and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular embodiments only, and is not intended to be limiting of the invention. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art. Furthermore, terms, such as those defined in commonly used dictionaries, should be interpreted as having a meaning that is consistent with their meaning in the context of the relevant art, and will not be interpreted in an idealized or overly formal sense unless expressly so defined herein.

While various embodiments of the present invention have been described above, it should be understood that they have been presented by way of example only, and not limitation. Numerous changes to the disclosed embodiments can be made in accordance with the disclosure herein, without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations, and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

What is claimed is:

1. A field-replaceable unit (FRU) identification circuit configured to identify an FRU electrically connected to a circuit board, the FRU identification circuit comprising:
a reference voltage source configured to provide a reference voltage;
a reference resistor having a first end and a second end, the first end of the reference resistor being electrically connected to the reference voltage source;
a plurality of comparators, each of the plurality of comparators having a first input, a second input, and an output, the first input of each of the plurality of comparators being electrically connected to the second end of the reference resistor; and
a plurality of comparator input voltage sources each configured to provide a comparator input voltage, each of the plurality of comparator input voltage sources being electrically connected to the second input of a respective one of the plurality of comparators,
wherein in response to the FRU being electrically connected to the circuit board, the outputs of the plurality of comparators are set to a distinct combination of logical values that uniquely identifies the FRU.

2. The FRU identification circuit of claim 1, wherein the FRU is a component of a fan module.

3. The FRU identification circuit of claim 1, wherein:
the FRU includes a source resistor; and
the reference voltage source, the reference resistor, and the source resistor form a voltage divider when the FRU is electrically connected to the circuit board, the voltage divider including a voltage divider output formed between the reference resistor and the source resistor.

4. The FRU identification circuit of claim 3, wherein when the FRU is electrically connected to the circuit board, the voltage divider output is electrically connected to the first input of each of the plurality of comparators.

5. The FRU identification circuit of claim 4, wherein the output of each respective one of the plurality of comparators is a logical value based on a comparison between (i) a voltage of the voltage divider output and (ii) the comparator input voltage of the comparator input voltage source electrically connected to the respective one of the plurality of comparators.

6. The FRU identification circuit of claim 5, wherein the output of each respective one of the plurality of comparators is a logical high value or a logical low value.

7. The FRU identification circuit of claim 6, wherein in response to the comparator input voltage of the respective one of the plurality of comparators being greater than the voltage of the voltage divider output, the output of the respective one of the plurality of comparators is set to a logical high value.

8. The FRU identification circuit of claim 6, wherein in response to the comparator input voltage of the respective one of the plurality of comparators being less than the voltage of the voltage divider output, the output of the respective one of the plurality of comparators is set to a logical low value.

9. The FRU identification circuit of claim 4, wherein the voltage of the voltage divider output is less than the reference voltage provided by the reference voltage source.

10. The FRU identification circuit of claim 4, wherein the voltage of the voltage divider output is less than the comparator input voltage of at least one of the plurality of comparator input voltage sources.

11. The FRU identification circuit of claim 1, wherein the reference voltage is greater than about 0 volts and less than or equal to about 20 volts.

12. The FRU identification circuit of claim 1, wherein the reference resistor has a resistance of about 1,000 ohms.

13. The FRU identification circuit of claim 1, wherein the source resistor has a resistance that is different than a resistance of the reference resistor.

14. The FRU identification circuit of claim 1, wherein each one of the plurality of comparator input voltages is different than a remainder of the plurality of comparator input voltages.

15. The FRU identification circuit of claim 1, wherein:
the plurality of comparators includes n comparators; and
the FRU identification circuit is configured to distinguish among n distinct FRU groups, each distinct FRU group including one or more FRUs having a distinct value of a characteristic and being identifiable by the outputs of the n comparators.

16. The FRU identification circuit of claim 15, wherein the outputs of then comparators are configured to generate at least n+1 distinct combinations of logical values.

17. The FRU identification circuit of claim 16, wherein one of the n+1 distinct combinations of logical values corresponds to no FRU being electrically connected to the circuit board, and wherein each remaining combination of logical values of the n+1 combinations of logical values corresponds to a distinct one of the n FRU groups.

18. The FRU identification circuit of claim 17, wherein:
the one of the n+1 distinct combinations of logical values corresponding to no FRU being electrically connected to the circuit board includes the output of each of the plurality of comparators being set to a logical high value; and
each remaining combination of logical values of the n+1 combinations of logical values includes the output of at least one of the plurality of comparators being set to a logical low value.

19. A computing device comprising:
a housing;
a circuit board disposed inside the housing; and
a field-replaceable unit (FRU) identification circuit formed on the circuit board, the FRU identification circuit including:
a reference voltage source configured to provide a reference voltage;
a reference resistor having a first end and a second end, the first end of the reference resistor being electrically connected to the reference voltage source;
a plurality of comparators, each of the plurality of comparators having a first input, a second input, and an output, the first input of each of the plurality of comparators being electrically connected to the second end of the reference resistor; and
a plurality of comparator input voltage sources each configured to provide a comparator input voltage, each of the plurality of comparator input voltage sources being electrically connected to the second input of a respective one of the plurality of comparators,
wherein in response to the FRU being electrically connected to the circuit board, the outputs of the plurality of comparators are set to a distinct combination of logical values that uniquely identifies the FRU.

20. A method of identifying a field-replaceable unit (FRU), the method comprising:
installing the FRU in a computing device such that the FRU is electrically connected to a circuit board of the computing device;
determining a logical value of an output of each of a plurality of comparators on the circuit board of the computing device;
identifying, based on the logical value of the output of each of the plurality of comparators, an FRU group to which the FRU belongs.
